(19) United States
(12) Patent Application Publication
(10) Pub. No.: US 2022/0406956 A1
(43) Pub. Date: Dec. 22, 2022

(54) INTEGRATED CIRCUIT WITH A GALVANICALLY-ISOLATED COMMUINCATION CHANNEL USING A BACK-SIDE ETCHED CHANNEL

(71) Applicant: TEXAS INSTRUMENTS INCORPORATED, Dallas, TX (US)

(72) Inventors: Swaminathan SANKARAN, Allen, TX (US); Baher HAROUN, Allen, TX (US); Gerd SCHUPPENER, Allen, TX (US); Scott Robert SUMMERFELT, Garland, TX (US); Benjamin COOK, Los Gatos, CA (US)

(21) Appl. No.: 17/680,981

(22) Filed: Feb. 25, 2022

Related U.S. Application Data
(60) Provisional application No. 63/213,551, filed on Jun. 22, 2021.

(51) Int. Cl. H01L 31/173; H01L 49/02

(52) U.S. Cl. CPC H01L 31/173; H01L 28/10; H01L 28/60

(57) ABSTRACT

An integrated circuit (IC) includes a substrate having a first surface and a second surface opposite the first surface. The substrate has a first region containing a first circuit and a second region containing a second circuit. The first circuit operates at a first supply voltage. The second circuit operates at a second supply voltage. The second supply voltage is higher than the first supply voltage. The IC includes a through wafer trench (TWT) extending from the first surface of the substrate to the second surface of the semiconductor substrate. The TWT separates the first region from the second region. A dielectric material is in the TWT. An interconnect region has layers of dielectric on the first surface of the substrate. The interconnect region is continuous over the first region, the second region, and the TWT. A non-galvanic communication channel is between the first and second circuits.

### CROSS-REFERENCE TO RELATED APPLICATIONS

This application claims priority to U.S. Provisional Application No. 63/213,551, filed Jun. 22, 2021, which is hereby incorporated by reference.

### BACKGROUND

In many systems, a first device communicates with a second device. In some such systems, the first and second devices may operate from two, very different supply voltages. For example, the first device may be a lower voltage (e.g., 5V) microcontroller, while the second device is a higher voltage (e.g., 300V) motor. Voltage isolation between the two devices is desirable to avoid damage to the lower voltage device.

### SUMMARY

In one example, an integrated circuit (IC) includes a substrate having a first surface and a second surface opposite the first surface. The substrate has a first region containing a first circuit and a second region containing a second circuit. The first circuit operates at a first supply voltage. The second circuit operates at a second supply voltage. The second supply voltage is higher than the first supply voltage. The IC includes a through wafer trench (TWT) extending from the first surface of the substrate to the second surface of the semiconductor substrate. The TWT separates the first region from the second region. A dielectric material is in the TWT. An interconnect region has layers of dielectric disposed on the first surface of the substrate. The interconnect region is continuous over the first region, the second region, and the TWT. A non-galvanic communication channel is between the first and second circuits.

In another example, a method of fabricating a die on a semiconductor wafer includes forming a first circuit in a first region of a semiconductor substrate having a first surface and a second surface opposite the first surface. The first circuit is configured to operate at a first supply voltage. The method also includes forming a second circuit in a second region of the semiconductor substrate. The second circuit is configured to operate at a second supply voltage higher than the first supply voltage. The method further includes forming a through wafer trench (TWT) extending from the first surface of the semiconductor substrate to the second surface of the semiconductor substrate. The TWT separates the first region from the second region. The method includes disposing a dielectric material in the TWT, and forming a non-galvanic communication channel between the first circuit and the second circuit in an interconnect region. The interconnect region has layers of dielectric disposed on the first surface of the substrate. The interconnect region is continuous over the first region, the second region, and the TWT.

### BRIEF DESCRIPTION OF THE DRAWINGS

FIG. 1 is a block diagram of a system in which devices on two separate semiconductor dies communicate with each over a communication channel in accordance with an example.

FIG. 2 is a block diagram of the system illustrating that one device is a transmit device and the other device is a receive device in accordance with an example.

FIGS. 3A and 3B are cross-sectional views of a single semiconductor die having both a transmit circuit and a receive circuit on the same die with an isolation barrier therebetween and having a transformer-coupled communication channel in accordance with an example.

FIG. 4 is an electrical circuit representation of the transformer-coupled communication channel in accordance with an example.

FIG. 5 is a frequency plot of the communication channel in accordance with an example.

FIGS. 6A and 6B are cross-sectional views of a single semiconductor die having both a transmit circuit and a receive circuit on the same die with an isolation barrier therebetween and having a capacitor-coupled communication channel in accordance with an example.

FIG. 7 is an electrical circuit representation of the capacitor-coupled communication channel in accordance with an example.

FIG. 8 is a cross-sectional view of a single semiconductor die having both a transmit circuit and a receive circuit on the same die with an isolation barrier therebetween and having an optically-coupled communication channel in accordance with an example.

FIG. 9 is an electrical circuit representation of the optically-coupled communication channel in accordance with an example.

FIGS. 10A-10K are cross-sectional views of a portion of a wafer illustrating process steps for fabrication of the through wafer trench in accordance with an example.

### DETAILED DESCRIPTION

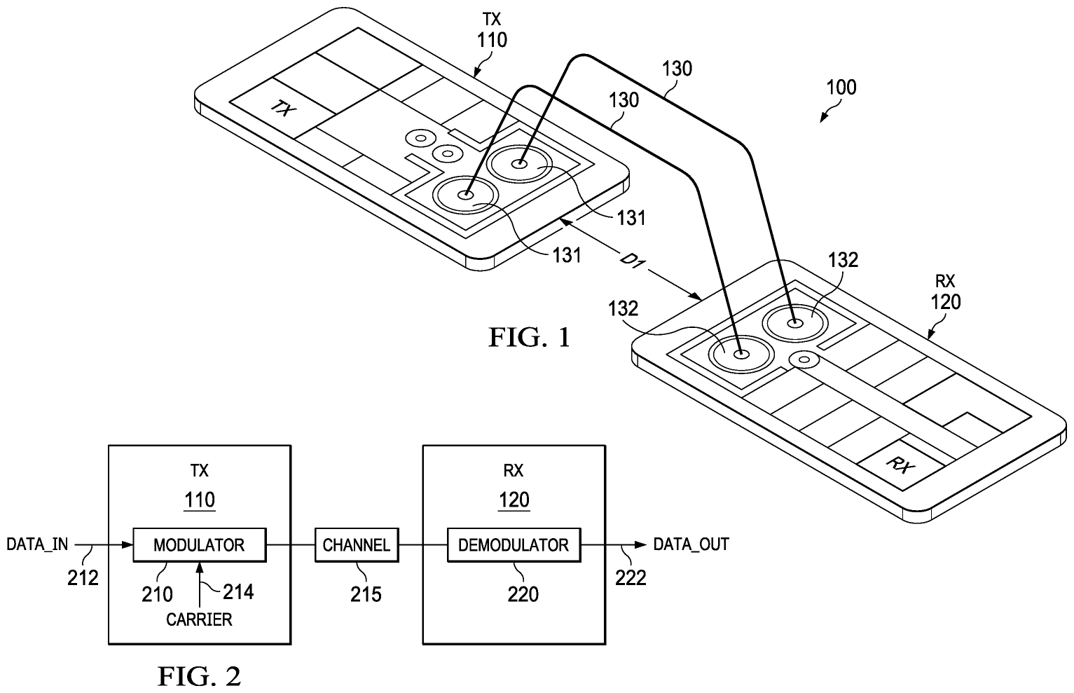

FIG. 1 shows an example of a system 100 including a first device 110 and second device 120. Each device has its own semiconductor die (“chip”). Thus, first device 110 includes one die and second device 120 is a separate die. The dies are separated by a distance D1 to provide sufficient voltage isolation between devices 110 and 120. In one example, device 110 is a transmitter operating at one supply voltage level, and device 120 is a receiver operating at a different supply voltage level. In a specific example, device 110 is or includes a microcontroller and device 120 is a motor controller. The microcontroller provides control signals over a communication channel 130 to the motor controller. The supply voltage level for device 120 may be significantly higher (e.g., 300V) than that of the supply voltage level of device 110 (e.g., 5V). Separation distance D1 is sufficiently larger to avoid arcing that otherwise might occur between the two devices which might damage device 100.

The communication channel may include bond wires interconnecting corresponding capacitors 131, 132 on devices 110 and 120. Based on the process technology implemented to fabricate devices 110 and 120, the speed of the communication channel is limited to a certain speed. However, it may be desirable to implement communication channels in such systems with faster and faster speeds. For example, the Universal Serial Bus (USB) 2.0 protocol implements speeds up to 480 mega-bits per second (Mbps) and USB 3.0 has speeds up to 4.8 giga-bits per second (Gbps). System 100 unfortunately may not be capable of such data rates.

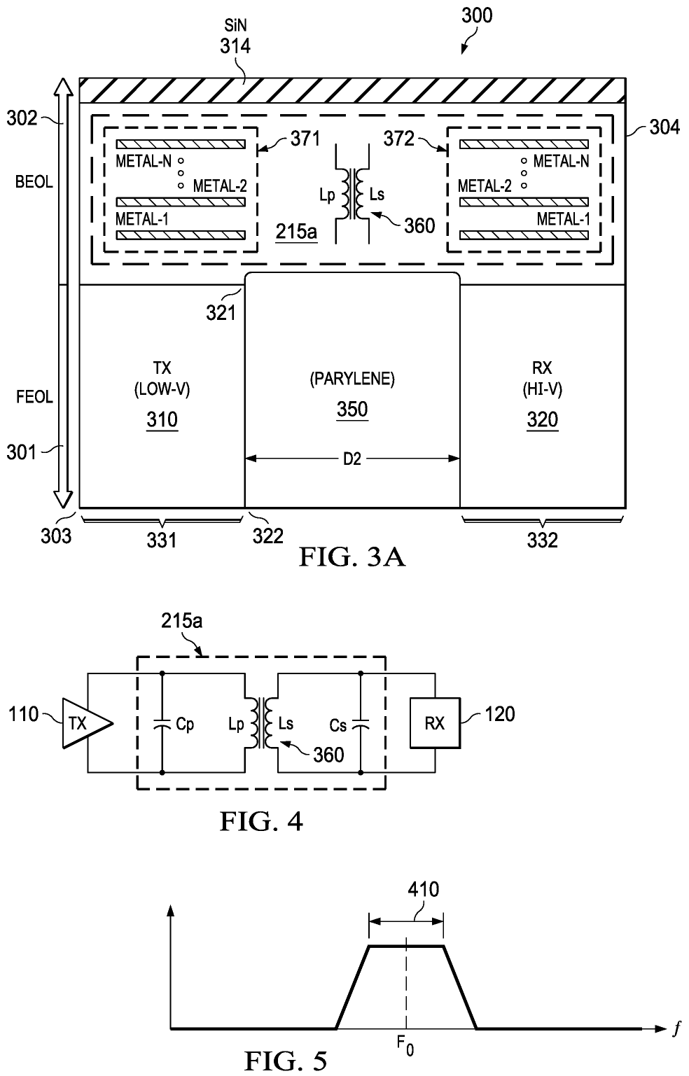

FIG. 2 illustrates further detail about the implementation of the communication channel between TX device 110 and RX device 120. The TX device 110 includes a modulator 210 which receives data (DATA_IN), modulates a carrier signal 214, and transmits the modulated carrier signal over a communication channel 215 to the RX device 120. The frequency of the carrier signal 214 may be substantially higher than the frequency of DATA_IN. The RX device 120 includes a demodulator 220 that receives the modulated signal from the communication channel 215, and demodulates the signal to recover the original data as DATA OUT 222.

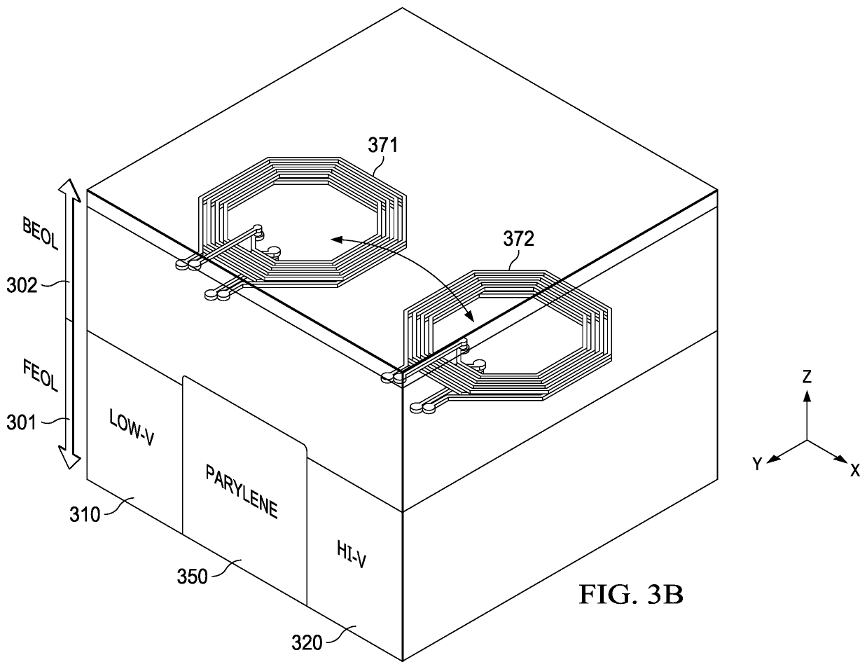

FIG. 3A is an example device 300 that has a single semiconductor die 303 on which a first circuit 310 (e.g., a TX circuit) and a second circuit 320 (e.g., a RX circuit) are fabricated. That is, the first and second circuits 310 and 320 are provided on the same semiconductor die 303. In other embodiments, second circuit 320 is the TX circuit and first circuit 310 is the RX circuit. In yet other embodiments, each of the circuits 310 and 320 may function as either the TX or the RX circuit. The semiconductor die 303 has a semiconductor substrate 301. The substrate 301 has a first surface 321 and a second surface 322 opposite the first surface 321. The substrate 303 has a first region 331 containing the first circuit 310 and a second region 332 containing the second circuit 320. The first circuit 310 is configured to operate at a first supply voltage. The second circuit 320 is configured to operate at a second supply voltage. The second supply voltage is higher than the first supply voltage. In one example, the first supply voltage for the first circuit 310 is in the range of 0.5 to 20V, while the second supply voltage is hundreds of volts (e.g., 100-1000V).

Device 300 also has a through wafer trench (TWT) 350 extending from the first surface 321 of the semiconductor substrate 301 to the second surface 331 of the semiconductor substrate. The TWT 350 separates the first region 310 from the second region 320. A dielectric material is disposed in the TWT 350. The TWT filled with a dielectric provides voltage isolation between the first and second regions 310 and 332 and thus between the first and second circuits 310 and 320. In one example, the dielectric fill material is fluorinated parylene (parylene-F or -HTC or -AF4). In other examples, the dielectric fill material may be a non-fluorinated parylene compound. In other examples, the dielectric fill material may include organic dielectric material such as epoxy, polyimide, silicone, Teflon, or benzocyclobutene (BCB). Alternatively, the dielectric fill material 110 may include inorganic dielectric material such as glass, ceramic or silicon dioxide-based inorganic material formed from siloxane-containing solution or sol-gel.

The device 300 also includes an interconnect region 302 (also called a back end of line, BEOL) having layers of dielectric and metal disposed on the first surface 321 of the substrate 301. The interconnect region is continuous over the first region 331, the second region 332, and the TWT 350. The interconnect region has a non-galvanic communication channel 215a (i.e., a galvanically-isolated commination channel) between the first region 331 and the second region 332. The width D2 of the TWT is fairly narrow. In one example, D2 is in the range of 5 microns to 50 microns, and in a specific example, D2 is 10 microns. D2 is narrow enough that a non-galvanic communication channel (such as those illustrated in FIGS. 3-8 and described below) can be formed between the first and second circuits 310 and 320.

In the example of FIG. 3A, the non-galvanic communication channel 215a is a lateral transformer-coupled communication channel which includes a first inductor 371 in the interconnection region 302 over the first region 331 of the semiconductor substrate that is magnetically-coupled to a second inductor 372 in the interconnection region over the second region 332 of the semiconductor substrate. The transformer-coupled communication channel in this example is lateral meaning that the two coils 371 and 372 are side-by-side spaced apart (along the X-axis) by the TWT 350, and are not stacked vertically along the Z-axis. Each inductor 371 and 372 comprises two or more layers of metal structures within the interconnection region (e.g., Metal-1, Metal-2, etc.). The multiple layers are interconnected by way of vias to form the inductor. Each inductor 371, 372 comprises a number of turns which may be the same or different between the two inductors. Reference numeral 360 identifies schematically a transformer that is formed using the two inductors 371, 372. The inductor 371 is represented as inductor Lp (the primary coil of the transformer), and inductor 372 is represented as inductor Ls (the secondary coil of the transformer). The width D2 of the TWT 350 is narrow enough that the two inductors 371 (Lp) and 372 (Ls) are able to be magnetically coupled to each other. FIG. 3B shows another perspective view in which additional detail is shown for inductors 371 and 372. Each coil 371 and 372 may be a generically circular coil as shown or have other shapes as desired.

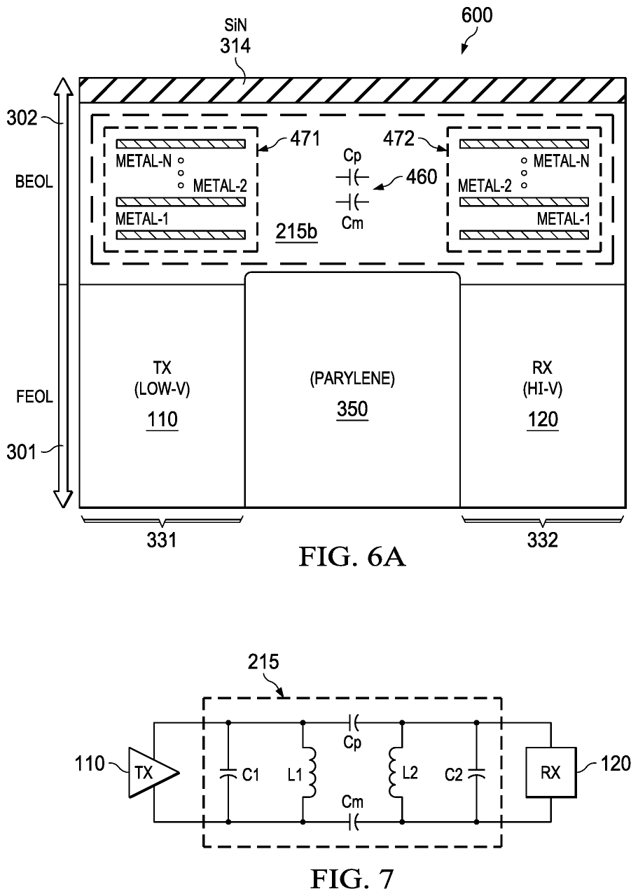

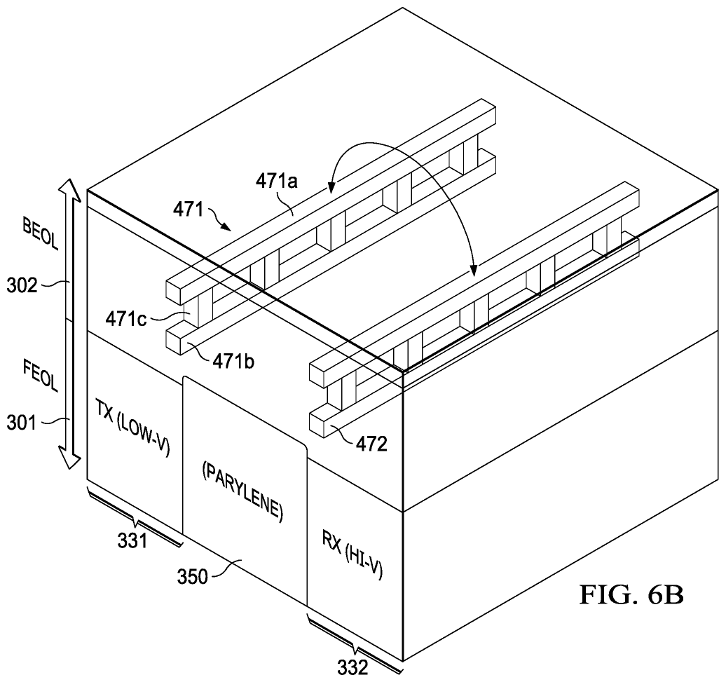

FIG. 4 is an electrical schematic of the transformer-coupled, non-galvanic communication channel 215a. The inductor 360 is shown disposed between the TX circuit 310 and the RX circuit 320. A primary side capacitor Cp also is formed within the interconnection region 302 over the first region 331 of the substrate 301. Similarly, a secondary side capacitor Cs is formed within the interconnection region 302 over the second region 332 of the substrate. The combination of the capacitors Cp and Cs and the transformer 360 creates a transformer-coupled communication channel 215a that has a target frequency and bandwidth as depicted in the frequency plot of FIG. 5. In one example, the center frequency F₀ of the frequency band is 3 GHz, and the bandwidth 410 of the frequency band is 3 GHz.

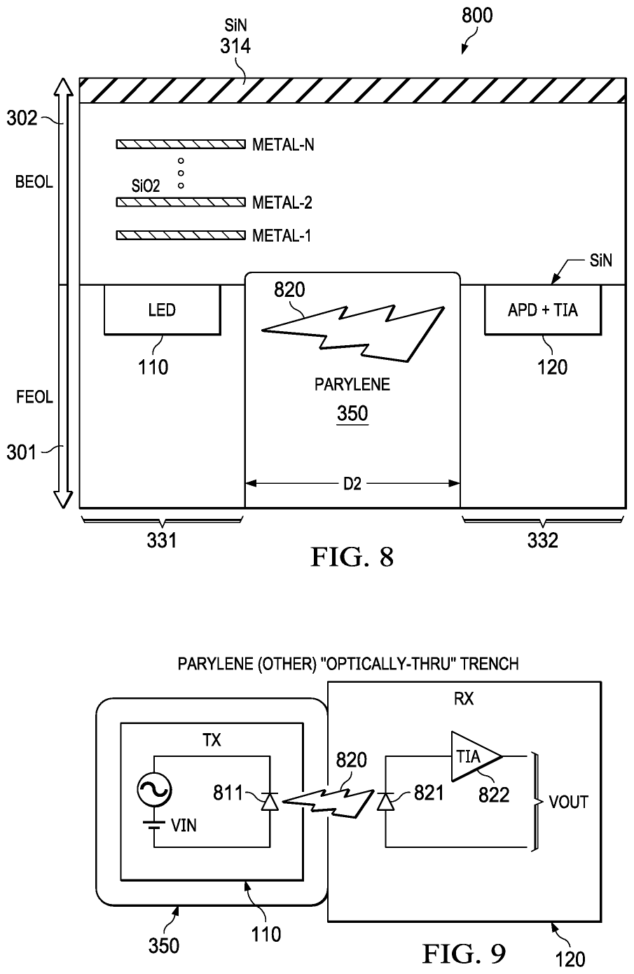

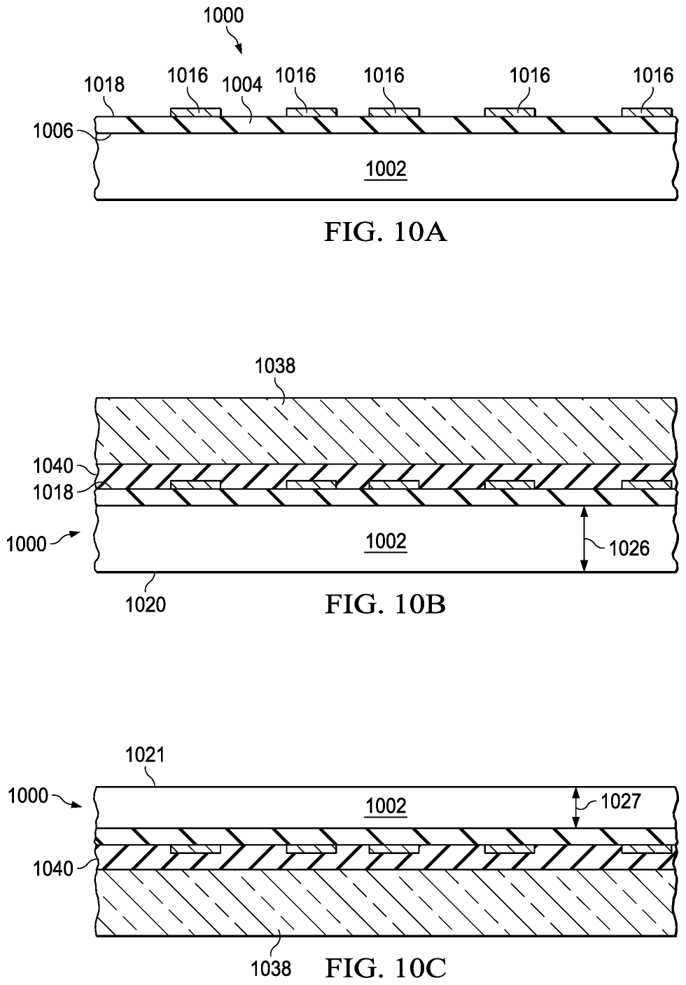

FIG. 6A shows an example of a semiconductor device 600 that is similar to FIG. 3A, but the communication channel 215b of semiconductor device 600 is a lateral, capacitively-coupled communication channel. The capacitors Cp and Cm for the communication channel are identified schematically at 460. The non-galvanic communication channel 215b includes a first conductive metal structure 471 of a capacitor in the interconnection region 302 over the first region 331 of the semiconductor substrate and a second conductive metal structure 372 in the interconnection region over the second region 332 of the semiconductor substrate. Each of the capacitor's conductive metal structures 471, 472 includes two or more layers of metal structures within the interconnection region (e.g., Metal-1, Metal-2, etc.). The multiple layers may be interconnected by way of vias to form the capacitor conductive portion. The width D2 of the TWT 350 is narrow enough that the two capacitor metal structures 471 and 472 are close enough to each other to form a satisfactory capacitor for use in a communication channel. In one example, the capacitors Cp and Cm are Metal-Oxide-Metal (MOM) capacitors. In another example, the capacitors Cp and Cm are Metal-Insulator-Metal (MIM) capacitors. The example of FIG. 6B shows that capacitor 471 includes metal structures 471a and 471b separated by an insulative (dielectric) layer 471c. Capacitor 472 is similarly constructed in this example. FIG. 7 is a corresponding schematic diagram and shows that additional components such as capacitors C1 and C2 and inductors L1 and L2 may be formed so as to implement the target frequency and bandwidth for the communication channel 215b.

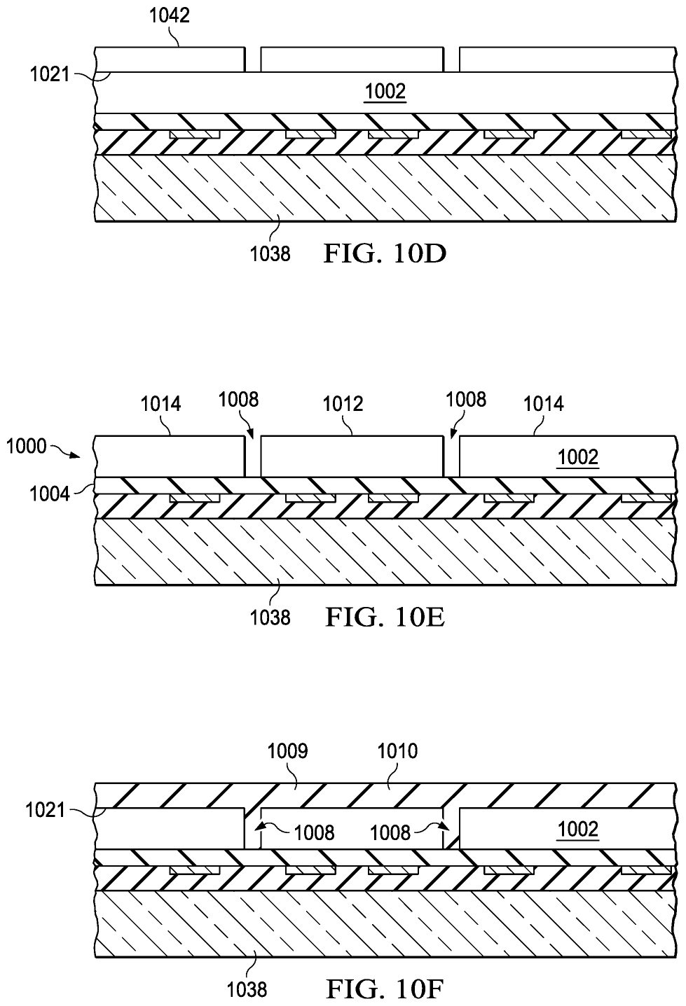

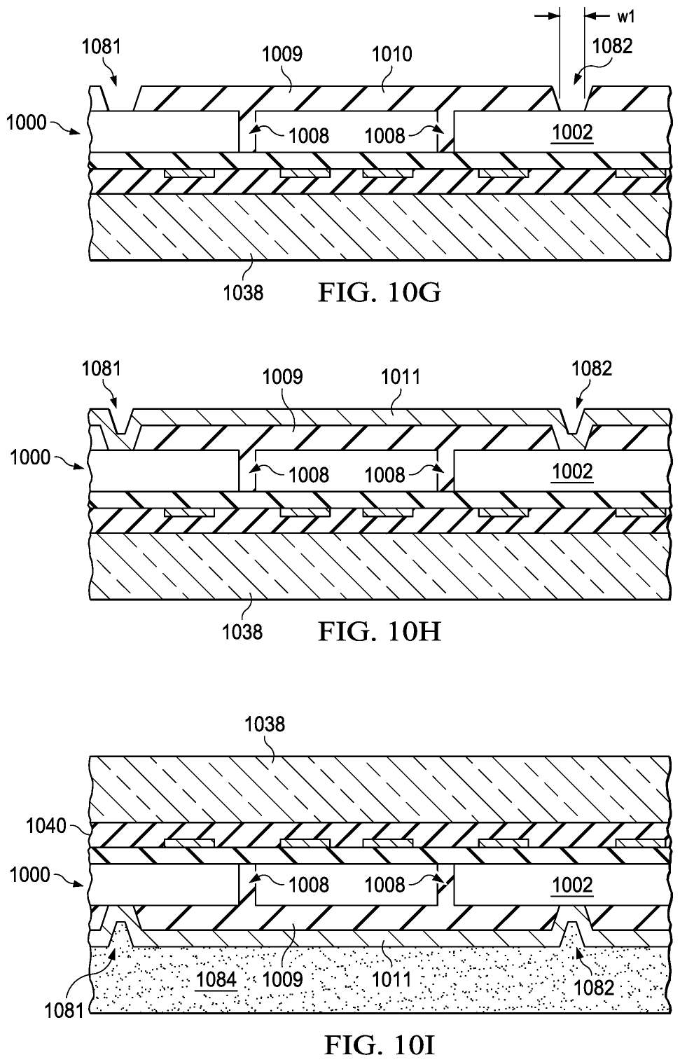

FIGS. 8 and 9 illustrate an example of the implementation of an optically-coupled communication channel through the dielectric-filled TWT 350 of a semiconductor device 800. In this example, the interconnect region 302 is not used to form components such as inductors and capacitors for a non-galvanic communication channel. The dielectric such as parylene that fills the TWT 350 is satisfactorily transmissive to certain wavelengths of light. As such, the first region 110 includes a light source within the first circuit 110 such as a light emitting diode (LED) that generates a light signal 820. The light signal 820 is transmitted through the dielectric of the TWT 350 and is detected by a photodetector within the RX circuit 120. The width D2 of the TWT 350 is narrow enough for the RX circuit's photodetector to detect the magnitude of the light signal 820, because the light signal 820 is not overly attenuated by the width D2 of the TWT 350.

FIG. 9 is an electrical circuit schematic of the optically-coupled communication channel. The TX circuit includes a light source 811. The RX circuit 120 includes a photodetector 821 which, in one embodiment is an avalanche photodiode (APD). The RX circuit 120 may also include a transimpedance amplifier (TIA) to amplify the signal from the photodetector 821.

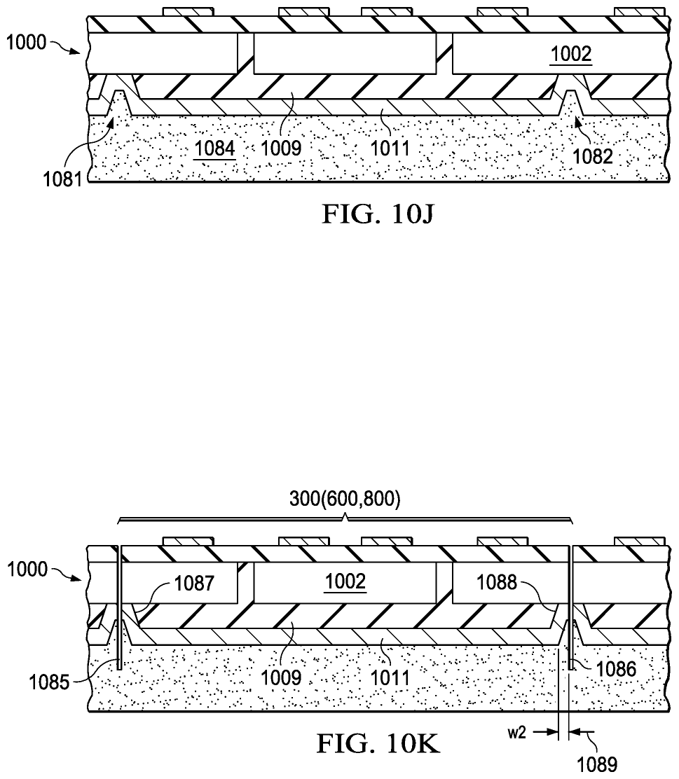

The TWT 350 filled with a dielectric (e.g., Parylene) provides adequate voltage isolation between circuits 110 and 120 but is narrow enough (dimension D2) to facilitate the formation of a non-galvanic communication channel. FIGS. 10A-10K illustrate an example process to form the TWT (identified as TWT 1008 below) and fill it with a dielectric.

Referring to FIG. 10A, the semiconductor device (e.g., device 300, 600, 800) is formed on a wafer 1000 that has a substrate 1002 comprising a semiconductor material such as silicon. In this example, the substrate 1002 is a bulk semiconductor wafer 1000 containing semiconductor devices 1000. The substrate 1002 may include an epitaxial layer of semiconductor material. The semiconductor device includes an interconnect region 1004 formed at a top surface 1006 of the substrate 1002. The interconnect region 1004 includes layers of dielectric material, one or more levels of metal lines, contacts connecting the metal lines to components in the substrate 1002, and possibly vias connecting the metal lines of different levels. In this example, the semiconductor device includes bond pads 1016 at, or proximate to, a top surface 1018 of the interconnect region 1004.

Referring to FIG. 10B, semiconductor wafer 1000 is mounted on a carrier 1038 with the top surface 1018 of the interconnect region 1004 nearest the carrier 1038 and a bottom surface 1020 of the substrate 1002 exposed. The carrier 1038 may be, for example, a silicon wafer or a ceramic or glass disk. The semiconductor wafer 1000 may be mounted to the carrier 1038 with a temporary bonding material 1040 such as Brewer Science WaferBOND® HT-10.10. A thickness 1026 of the substrate 1002 may initially be 500 microns to 600 microns, for example a full thickness of a commercial silicon wafer.

Referring to FIG. 10C, the thickness 1027 of substrate 1002 is reduced to approximately 100 microns, resulting from thinning the substrate 1002, for example by backgrinding. The exposed surface 1021 of substrate 1002 may then be polished using known or later developed techniques, such as chemical mechanical polishing (CMP). Other values of the thickness 1026, 1027 of the substrate 1002 are within the scope of this example.

Referring to FIG. 10D, a TWT mask 1042 is formed at the bottom surface 1021 of the substrate 1002 to expose an area for the TWTs. In an example, the TWT mask 1042 includes, for example, photoresist formed by a photolithographic process. Forming the TWT mask 1042 of photoresist has an advantage of low fabrication cost and may be appropriate for thinned substrates 1002. In another example, the TWT mask 1042 includes a hard mask material such as silicon nitride, silicon carbide or amorphous carbon, formed by a plasma enhanced chemical vapor deposition (PECVD) process. Forming the TWT mask 1042 of hard mask material has an advantage of durability and dimensional stability and may be appropriate for full-thickness substrates 1002.

Referring to FIG. 10E, semiconductor material of the substrate 1002 is removed in the areas exposed by the TWT mask 1042 to form the trenches 1050 to subsequently be filled with the dielectric fill material. The semiconductor material of the substrate 1002 may be removed by a deep reactive ion etch (DRIE) process. One example of a DRIE process, referred to as the Bosch process, alternately removes material at a bottom of an etched region and passivates sidewalls of the etched region, to maintain a desired profile of the etched region. Another example is a continuous DRIE process which simultaneously alternately removes material at a bottom of an etched region and passivates sidewalls of the etched region. Trenches 1050 are formed extending partially through the substrate 1002 towards the interconnect region 1004. In the case of bulk-wafer processing (that does not include a silicon-on-insulator (SOI) layer), the etch process automatically stops when it reaches the interconnect region 1004. In the case of an SOI process, the etch process automatically stops when it reaches a dielectric layer within the SOI structure.

Referring still to FIG. 10E, the TWT mask 1042 of FIG. 10D is removed. Photoresist in the TWT mask 1042 may be removed by an ash process or an ozone etch process, followed by a wet clean process. Hard mask material in the TWT mask 1042 may be removed by a plasma etch process which is selective to the semiconductor material in the substrate 1002 and the dielectric layers in the interconnect region 1004.

Referring to FIG. 10F, a dielectric polymer 1010 is deposited into the TWTs 1008 and onto backside surface 1021 of substrate 1002 to form a backside dielectric polymer layer 1009. In this example, parylene-F is the dielectric polymer 1010. In another example, parylene-HT or parylene-AF4 may be used. Parylene's deposition process eliminates the wet deposition method used for other dielectric materials such as epoxy, silicone, or urethane. It begins in a chemical-vacuum chamber, with raw, powdered parylene dimer placed in a loading boat, and inserted into a vaporizer. The dimer is initially heated to between 100 degrees C. to 150 degrees C., converting the solid-state parylene into a gas at the molecular level. The process requires consistent levels of heat; the temperature should increase steadily, ultimately reaching 1080 degrees C., sublimating the vaporous molecules and splitting it into a monomer.

The vaporous molecules are then drawn by vacuum onto substrate 1002 in the coating chamber, where the monomer gas reaches a final deposition phase, a cold trap. Here, temperatures are cooled to levels sufficient to remove any residual parylene materials pulled through the coating chamber from the substrate, between −90 degrees and −120 degrees C.

Parylene's complex and specialized vapor-phase deposition technique ensures that the polymer can be successfully applied as a structurally continuous backside dielectric polymer layer 1009 while being entirely conformal to the characteristics of TWT region(s) 1080 that are formed in substrate 1002.

In another example, TWTs 1008 and backside dielectric layer 1009 may be formed with other types of dielectric material, such as fluid droplets containing uncured epoxy, uncured polyimide, uncured BCB, ceramic slurry, sol-gel, siloxane-containing fluid such as methyl-silsesquioxane (MSQ), or glass. The dielectric-containing fluid droplets may include solvent or other volatile fluid, which is subsequently removed. The dielectric-containing fluid droplets may include two reactive component fluids, such as epoxy resin and hardener, which are mixed just prior to delivery from a droplet delivery apparatus. The dielectric-containing fluid in the TWTs 1008 is cured, dried or otherwise processed, as necessary, to form the dielectric material 1010 in the TWTs 1008 and backside dielectric layer 1009. The semiconductor wafer 1000 may be, for example, baked in a vacuum or inert ambient to convert the dielectric-containing fluid into dielectric material 1010. Some of these materials can use nano-size particles which will densify at low temperatures. In some cases, a low temperature glass powder might be used and then heated hot enough to melt and hence densify and fill gaps.

Referring to FIG. 10G, backside dielectric polymer layer 1009 is processed to remove the parylene from cut-line regions 1081, 1082 that will be sawn or otherwise cut to separate the various devices 300 (600, 800) from each other. One reason to remove the parylene from the cut line regions is to keep it from interfering with the cutting process. Another reason is to allow a diffusion barrier 1011 (see FIG. 10H) to be placed on the backside dielectric layer 1009 that will not expose parylene backside layer 1009 by the cutting process. In this example, the edges of backside dielectric layer 1009 at cut-line regions 1081, 1082 are tapered slightly to allow a smooth deposition of diffusion barrier layer 1011 (FIG. 10H).

Referring still to FIG. 10G, in one example a thick photoresist formed by a photolithographic process and a polymer etch using oxygen is used to remove the parylene from cut lines 1081, 1082. In another example, a hard mask material such as silicon nitride, silicon carbide or amorphous carbon formed by a plasma enhanced chemical vapor deposition (PECVD) process is used to remove parylene from cut line regions 1081, 1082. In another example, a laser ablation process is used to remove parylene from cut line regions 1081, 1082.

Referring to FIG. 10H, a diffusion barrier layer 1011 is deposited over backside dielectric polymer layer 1009. In one example, diffusion barrier layer 1011 is a layer of SiN that is thick enough such that the CTE mismatch with parylene layer 1009 does not crack diffusion barrier 1011. In another example, diffusion layer 1011 is a metal diffusion barrier. Some examples of typical interconnect or packaging metals include Ta, Ti, TiW, TaN, TiN, Al, Cu, Ag, or Au. In this case, copper (Cu), for example, is electroplated onto an adhesion layer Cu seed layer on top of a titanium (Ti) or titanium tungsten (TiW) barrier layer using a sputter, e-beam, CVD or later developed plating technique. In some examples, a pattern may be used to deposit thick Cu only in areas of dielectric polymer layer 1009 that need to be protected from moisture absorption.

Prior to depositing diffusion barrier 1011, parylene 1010 is baked to remove any latent moisture and to densify the parylene. Removing moisture from parylene may improve its resistivity by a factor of, for example, 100 times. The resistivity of the parylene typically requires lower temperatures for long times (such as 250 degrees C. for 24 hour) or higher temperatures for short times (400 degrees C. for 1 hour). Further baking typically improves the resistivity although too much baking especially in oxygen environments may result in degradation. After baking, diffusion barrier 1011 should be applied in a timely manner to prevent diffusion of moisture back into the parylene 1010.

Referring to FIG. 10I, semiconductor wafer 1000 is mounted on tape 1084 to provide support while carrier 1038 is removed. Tape 1084 is a known or later developed tape that is used in the fabrication of ICs.

Referring to FIG. 10J, semiconductor wafer 1000 is removed from the carrier 1038 of FIG. 10I. The semiconductor wafer 1000 may be removed, for example, by heating the temporary bonding material 1040 of FIG. 10I to soften the temporary bonding material 1040 using a laser or other heat source, and laterally sliding the semiconductor wafer 1000 off the carrier 1038. The temporary bonding material 1040 is subsequently removed, for example by dissolving in an organic solvent.

Referring to FIG. 10K, the multiple semiconductor devices 300 (or 600 or 800) included on semiconductor wafer 1000 are singulated as indicated at example cut lines 1085, 1086 using known or later developed singulation techniques, such as mechanical sawing, laser cutting, etc. Many additional cut lines (not shown) are formed to singulate all the semiconductor devices that were fabricated in parallel on wafer 1000.

Referring still to FIG. 10K, edges of backside dielectric polymer 1087, 1088 are not exposed by the singulation process, and diffusion barrier 1011 remains intact to completely seal and protect backside dielectric layer 1009 due to the removal of a portion of the backside dielectric layer 1009 in cutline region 1081, 1082 (FIG. 10G) prior to deposition of diffusion barrier 1011. Referring to FIG. 10G, the portion of parylene that is removed from cut-line region 1081, 1082 has a width w1 that is wide enough so that after diffusion barrier layer 1011 is applied, there is still a space 1089 having a width w2 between the edge of backside dielectric layer 1009 and the peripheral edge substrate 1002 of the IC that is wide enough so that edges 1087, 1088 of backside dielectric polymer layer 1009 are not exposed by the singulation process. Referring still to FIG. 10K, each of the multiple semiconductor devices are then packaged using known or later developed IC packaging techniques.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Unless otherwise stated, “about,” “approximately,” or “substantially” preceding a value means +/−10 percent of the stated value.

Modifications are possible in the described embodiments, and other embodiments are possible, within the scope of the claims.

What is claimed is:

1. An integrated circuit (IC), comprising:
a semiconductor substrate having a first surface and a second surface opposite the first surface, the semiconductor substrate having a first region containing a first circuit and a second region containing a second circuit, the first circuit configured to operate at a first supply voltage, the second circuit configured to operate at a second supply voltage, the second supply voltage higher than the first supply voltage;
a through wafer trench (TWT) extending from the first surface of the semiconductor substrate to the second surface of the semiconductor substrate, the TWT separating the first region from the second region;
a dielectric material in the TWT;
an interconnect region having layers of dielectric on the first surface of the substrate, the interconnect region being continuous over the first region, the second region, and the TWT; and
a non-galvanic communication channel between the first circuit and the second circuit.

2. The IC of claim 1, wherein the non-galvanic communication channel is a transformer-coupled communication channel comprising:
a first inductor in the interconnection region over the first region of the semiconductor substrate; and
a second inductor in the interconnection region over the second region of the semiconductor substrate.

3. The IC of claim 1, wherein the non-galvanic communication channel is a capacitor-coupled communication channel comprising:
a first capacitor metal structure in the interconnection region over the first region of the semiconductor substrate; and
a second capacitor metal structure in the interconnection region over the second region of the semiconductor substrate.

4. The IC of claim 3, wherein at least one of the first or second capacitors includes at least one of a metal-oxide-metal or a metal-insulator-metal capacitor.

5. The IC of claim 1, wherein the non-galvanic communication channel is an optically-coupled communication channel in which:
the first circuit includes a light source configured to transmit a light signal through the dielectric material in the TWT; and
the second circuit includes a photodetector configured to receive the light signal.

6. The IC of claim 5, wherein the light source is a light emitting diode, and the photodetector is an avalanche photodiode.

7. The IC of claim 1, wherein the dielectric material is a parylene compound.

8. The IC of claim 1, wherein the dielectric material is a fluorinated parylene compound.

9. The IC of claim 1, wherein the TWT has a width in a range of 3-50 microns.

10. An integrated circuit (IC), comprising:
a semiconductor substrate having a first surface and a second surface opposite the first surface, the semiconductor substrate having a first region containing a first circuit and a second region containing a second circuit, the first circuit configured to operate at a first supply voltage, the second circuit configured to operate at a second supply voltage, the second supply voltage higher than the first supply voltage;
a through wafer trench (TWT) extending from the first surface of the semiconductor substrate to the second surface of the semiconductor substrate, the TWT separating the first region from the second region;
a dielectric material in the TWT;
an interconnect region having layers of dielectric on the first surface of the substrate, the interconnect region being continuous over the first region, the second region, and the TWT; and
a galvanically-isolated communication channel between the first circuit and the second circuit, the galvanically-isolated communication channel is in the interconnect region.

11. The IC of claim 10, wherein the galvanically-isolated communication channel is a transformer-coupled communication channel comprising:
a first inductor in the interconnection region over the first region of the semiconductor substrate; and
a second inductor in the interconnection region over the second region of the semiconductor substrate.

12. The IC of claim 10, wherein the galvanically-isolated communication channel is a capacitor-coupled communication channel comprising:
a first capacitor metal structure in the interconnection region over the first region of the semiconductor substrate; and
a second capacitor metal structure in the interconnection region over the second region of the semiconductor substrate.

13. The IC of claim 12, wherein at least one of the first or second capacitors includes at least one of a metal-oxide-metal or a metal-insulator-metal capacitor.

14. The IC of claim 10, wherein the dielectric material is a parylene compound.

15. A method of fabricating a die on a semiconductor wafer, the method comprising:
forming a first circuit in a first region of a semiconductor substrate having a first surface and a second surface opposite the first surface, the first circuit configured to operate at a first supply voltage;
forming a second circuit in a second region of the semiconductor substrate, the second circuit configured to operate at a second supply voltage higher than the first supply voltage;
forming a through wafer trench (TWT) extending from the first surface of the semiconductor substrate to the second surface of the semiconductor substrate, the TWT separating the first region from the second region;
disposing a dielectric material in the TWT; and
forming a non-galvanic communication channel between the first circuit and the second circuit in an interconnect region, the interconnect region having layers of dielectric on the first surface of the substrate, the interconnect region being continuous over the first region, the second region, and the TWT.

16. The method of claim 15, wherein forming the non-galvanic communication channel comprises:
forming a first inductor in the interconnection region over the first region of the semiconductor substrate; and
forming a second inductor in the interconnection region over the second region of the semiconductor substrate.

17. The method of claim 15, wherein forming the non-galvanic communication channel comprises:
forming a first capacitor metal structure in the interconnection region over the first region of the semiconductor substrate; and
forming a second capacitor metal structure in the interconnection region over the second region of the semiconductor substrate.

18. The method of claim 15, wherein disposing the dielectric material in the TWT comprises disposing a parylene compound in the TWT.

19. The method of claim 15, wherein disposing the dielectric material in the TWT comprises disposing a fluorinated parylene compound in the TWT.

20. The method of claim 15, wherein forming the TWT comprises forming the TWT to have a width in a range of 3-50 microns.
